(19) United States
(12) Patent Application Publication
(10) Pub. No.: US 2016/0139197 A1
(43) Pub. Date: May 19, 2016

(54) CIRCUIT, SENSOR AND METHOD FOR DETERMINING AN OSCILLATION BEHAVIOR

(71) Applicant: ZF FRIEDRICHSHAFEN AG, Friedrichshafen (DE)

(72) Inventor: Thomas LUBER, Dinklage (DE)

(21) Appl. No.: 14/899,839

(22) PCT Filed: May 26, 2014
(86) PCT No.: PCT/EP2014/060774

§ 371 Date: Dec. 18, 2015

(30) Foreign Application Priority Data
Jun. 27, 2013 (DE) 10 2013 212 424.4

(51) Int. Cl. G01R 31/28; G01R 23/02

(52) U.S. Cl. CPC G01R 31/2836; G01R 23/02

(57) ABSTRACT

A circuitry comprises at least one oscillating circuit section, wherein the circuit section comprises a circuit component, which can be affected by the external influence such that an oscillation behavior of the circuit section can be altered by the external influence. The circuitry is furthermore designed thereby to determine the oscillation behavior of the circuit section by a sampling at numerous defined frequencies. As a result, it may be possible to improve a compromise regarding the production and implementation of such a circuitry.

Exemplary embodiments relate to a circuitry, a sensor and a method for determining an oscillation behavior.

There is a demand in many fields of technology for detecting an external influence. One example is sensors that are able to detect an approach of an object, for example, toward another object. These sensors can, for example, be a proximity sensor, a button, or another appropriate sensor. These sensors can thus comprise a circuitry, which makes it possible to detect the external influence. Sensors of this type are used in the field of keypads, in the automotive field, plant construction and other disciplines of mechanical engineering.

By way of example, sensors are used for applications pertaining to safety in vehicles. In these cases, it may be advisable for them to exhibit a high degree of reliability and, if applicable, to be able to be subjected to a diagnosis. With simple electrical contacts, and with technologically simple means, in some cases, this can only be accomplished with difficulty, because the contacts may become worn, for example. The same may also apply to a diagnosis in the case of a short circuit or an interruption.

EP 1 424 250 A2 relates to a device for monitoring the buckled state of a seatbelt for vehicles. The monitoring device functions with a sensor that directly measures an inductance change or a coupling factor change. With a solution of this type, however, an individual comparison may possibly be necessary.

Similar demands exist not only in the field of seatbelt buckles and other applications in the automotive field, but also in other engineering fields.

There is, therefore, a demand for improving a compromise regarding the production and implementation for such applications. This demand is fulfilled by a circuitry according to claim 1, a sensor according to claim 14, and a method according to claim 15.

With an exemplary embodiment of a circuitry having at least one circuit section that is capable of oscillation, this circuitry comprises a circuit component, which can be affected by an external influence such that an oscillation behavior of the circuit section can be altered by the external influence. The circuitry is furthermore designed to determine the oscillation behavior of the circuit section by sampling numerous defined frequencies.

Thus, one exemplary embodiment is based on the fact that a compromise regarding the production and implementation can be improved in that the circuitry is designed to be able to determine the oscillation behavior of the circuit section by a sampling at numerous defined frequencies. As a result, it may also be possible to eliminate an adjustment of the circuitry to the concrete application using comparably simple means, in that the numerous defined frequencies are found in a frequency range such that, independently of an individual adjustment of a single circuitry in accordance with an exemplary embodiment, the oscillation behavior affected by the external influence can be determined by the circuitry, and thus, if applicable, can be attributed to the external influence.

The oscillating circuitry section that is capable of oscillation can, for example, comprise an electrical oscillating circuit, or may be formed by such. An electrical oscillating circuit in this case is an electrical assembly that is capable of resonance, typically comprising an inductive circuit element and a capacitive circuit element. These are connected such that they can execute an electrical oscillation.

The inductive circuit element, as well as the capacitive circuit element can be formed here by individual circuit elements, but also by independent circuitries, in which their impedance (alternating current resistance) is dependent on a frequency applied to them, which is similar to a coil or a capacitor. Thus, an inductive circuit element, for example, can have an impedance that increases in value with the frequency, and a capacitive circuit element having an impedance that decreases in value with the frequency. This behavior can, in the case of an inductive circuit element, be linear or substantially linear, or it can also follow a polynomial equation, or a more complex equation. Accordingly, in the case of a capacitive circuit element, the behavior can be inversely proportional, thus, for example, it can be linearly, or substantially linearly, inversely proportional, or it can also follow a fractional rational, or more complex behavior. Additionally or alternatively, the impedance behavior can also comprise a phase shift, possibly dependent on the frequency, as is the case, for example, with a coil as an example of an inductive circuit element, or a capacitor as an example of a capacitive circuit element.

The oscillation behavior comprises a behavior of a signal thereby with respect to its strength as a function of the frequency applied to or present at the circuit component or the circuitry section. The oscillation behavior can thus potentially be determinable by determining or detecting the signal strengths at the frequencies of the numerous defined frequencies. This also comprises, in particular, the possibility of an approximate determination, as can be executed by means of a corresponding determination of a few, e.g. just two, frequencies, but it can also be executed at numerous frequencies.

The circuit component can be affected by the external influence thereby, thus it can be modified or controlled with respect, for example, to the course of its impedance as a function of the frequency. The circuit component can be an inductive circuit element, for example, in which the external influence is accompanied by a change in an inductance, and thus a change in the impedance. In this case, the external influence can comprise the approach or withdrawal of an object that affects the inductance of the inductive circuit element.

The circuit component can likewise be a capacitive circuit element, for example, in which the external influence results in a change in the capacitance value, and thus, likewise in a change in the impedance. In such a case, the external influence can comprise, for example, a movement of a dielectric medium, through which the capacitance value of the capacitor is modified. Likewise, this can also be a change, for example, in a spacing of an electrode of the capacitive circuit element to another electrode of the capacitive circuit element. By this means as well, the capacitance value of the capacitive circuit element can be affected, and thus a change in the impedance of the capacitive circuit element can be brought about.

The circuit component can also, likewise be a resistive circuit element, thus a resistor, for example, the resistance of which, and thus its impedance, is modified with respect to the external influence. Depending on the concrete implementation, this can occur, for example, through a mechanical deformation of the resistor, through a magnetic influence on the resistor, and/or through a thermal influence on the resistor, or a corresponding resistive circuit element. Its impedance value can also be affected by this, and thus an oscillation behavior of the oscillating circuit section can be altered.

The alteration of the oscillation behavior through the external influence can, optionally, be reversible thereby, but it can, however, possibly exhibit a hysteretic behavior. If, for example, in a first state of the external influence, there is a first oscillation behavior of the circuit section, and if the first state is changed to a second state of the external influence, such that a second oscillation behavior, differing from the first oscillation behavior, is adopted by the circuit section, then the first oscillation behavior, or a third oscillation behavior that is at least similar to the first oscillation behavior can be adopted in turn through a subsequent return to the first state of the external influence. The latter case, of the third oscillation behavior, can correspond to the presence of a hysteretic behavior thereby, while the first case corresponds to a non-hysteretic behavior, or a hysteretic behavior outside of the hysteresis.

Optionally, the circuitry according to an exemplary embodiment can be designed to provide the numerous defined frequencies independently of the oscillation behavior of the circuit section. Thus, the frequencies of the numerous frequencies can be defined, for example, even before the concrete oscillation behavior of the circuit section is fully known, when a predefined or defined state of the external influence is present. As a result, it may also be possible, for example, to select the frequencies of the numerous frequencies independently of component and other tolerances of the circuit section, and thus to circumvent, or at least simplify, a concrete coordination of the circuitry at its circuit section. Likewise, it may also be possible to make the behavior of the circuitry less sensitive with respect to changes to the operating parameters. In this manner, where applicable, aging or changes due to temperature, or other changes as well to the operating parameters can have a reduced influence on the obtainable precision. In this manner, the oscillation behavior of the circuit section can be determined in a more systematic manner, for example.

Additionally or alternatively, the circuitry according to an exemplary embodiment can also comprise a frequency generator, which is designed to provide the circuit section with the numerous defined frequencies. Through the provision of the frequency generator, it may also be possible to provide the circuit section with the individual frequencies of the numerous frequencies in a controlled manner, and thus, potentially, to enable a more precise determination of the oscillation behavior.

The frequency generator can provide the circuit section with a frequency signal thereby, if applicable, which comprises a temporal sequence of the sub-signals wherein the sub-signals are substantially assigned, in each case, to one frequency of the numerous frequencies. The frequency in question, from the numerous frequencies, can correspond thereby to a fundamental frequency, for example, of the sub-signal in question.

Optionally, the frequencies of the numerous frequencies can be disposed equidistantly, for example, in a frequency range in which the frequencies of the numerous frequencies lie. In other words, the frequencies of the numerous frequencies, insofar as these comprise at least three different frequencies, can lie within the frequency range, for example, such that a difference between two frequencies of the numerous frequencies corresponds in terms of its value to a smallest absolute frequency difference of all of the frequencies of the numerous frequencies, or a whole number multiple thereof.

As shall be explained below, the frequency generator can optionally be designed, for example, as a part of a programmable hardware component, thus, can be comprised by such, for example. Thus, the frequency generator can, for example, comprise a digital interface of a programmable hardware component, at which a clock signal can be emitted as a frequency signal having a frequency that can be modified, controlled or regulated in a targeted manner. The frequency signal can thus comprise a square wave signal of different frequencies, for example. A programmable hardware component of this type can be formed by a processor, a microcontroller (μcontroller, μC, MCU), a digital signal processor (DSP) or another appropriate hardware, as shall be explained below. As a result, it may be possible to already simplify production due to a reduced number of components. Additionally or alternatively, it may also be possible to obtain a greater flexibility regarding the use and/or a determination of the oscillation behavior. With other exemplary embodiments, however, the frequency generator can also be designed as a separate, analog, digital or hybrid component or circuitry.

Additionally or alternatively, the circuitry can also comprise an evaluation unit, in accordance with an exemplary embodiment, which is coupled to the circuit section, and is designed to detect at least one signal strength of the circuit section, in each case, via the coupling, for frequencies of the numerous defined frequencies. As a result, it may be possible to simplify the determination of the oscillation behavior. Optionally, the evaluation unit—as with the frequency generator—can be designed as a component of a potentially implemented programmable hardware component. As a result, it may also be possible to implement more complex determination methods, by means of which a more precise and/or quicker determination of the oscillation behavior may be possible. As a matter of course, the evaluation unit can also be designed as a separate circuitry or structural component. It can be implemented as a digital, analog or hybrid component. In the case of a digital or hybrid implementation, the evaluation unit can comprise, for example, an analog/digital converter (ADC).

If, for example, the evaluation unit is likewise implemented in the framework of a programmable hardware component, it may also be possible, by means of an assignment, in the form of a table or matrix for example, to assign a respective signal strength to each of the individual frequencies of the numerous frequencies, and thus to obtain a frequency/signal strength classification. On the basis of this frequency/signal strength classification, it is then also possible to realize and implement a more complex determination algorithm. In other words, frequency/signal strength pairs of values can be archived or stored in a memory of the evaluation unit, or a memory assigned to this evaluation unit, based on which the determination of the oscillation behavior is then executed by the evaluation unit.

The signal strengths can represent, for example, an electric measurement, or comprise such, such as a voltage or a current strength. The signal strengths can—depending on the detection technique that is used—also represent a differential value or a proximity thereof, for example.

Optionally, with such an exemplary embodiment, a circuitry of the evaluation unit can be designed to determine an extreme of the oscillation behavior based on the detected signal strengths. As a result, it may be possible to determine data that are characteristic for the oscillation behavior, and thus simplify the determination or the further use of the determined oscillation behavior. As such, the oscillation behavior frequently exhibits a local or global extreme in its resonance frequency, thus the frequency at which the circuit section resonates. The extreme can be a (local or global) maximum or minimum, for example. As a matter of course, a precision regarding the position or frequency of the determined extreme may be dependent on concrete parameters for the exemplary embodiment in question.

With such an exemplary embodiment, the numerous defined frequencies can optionally comprise at least one first frequency, one second frequency and one third frequency, which, optionally, can be different from one another. For this, a second signal strength at the second frequency can be greater or lesser than a first signal strength at the first frequency and a third signal strength at the third frequency. The first frequency is lower than the second frequency thereby, and the third frequency is higher than the second frequency. The evaluation unit can be designed thereby to determine the extreme of the oscillation behavior, based at least on the first, second and third signal strengths, by means of interpolation. As a result it may also be possible to improve a precision of the determination of the position of the extreme—and thus, potentially the resonance frequency—by means of the implemented interpolation. Likewise, it may also be possible to reduce a number of the detected signal strengths, and thus a number of the frequencies of the numerous frequencies, and thus to obtain a higher determination speed and/or a higher precision.

Additionally or alternatively, with an exemplary embodiment a first operating state can be assigned to a first frequency range, and a second operating state can be assigned to a second frequency range. In this case, the evaluation unit can also be designed to determine whether the first operating state or the second operating state is active, when a frequency of the extreme lies in the frequency ranges assigned to the first operating state. As a result, it may be possible to enable a comparably simple and/or, if applicable, with respect to changes in the operating parameters and/or the parameters for the circuitry, robust determination of the operating states thereof, in that a position of the frequency of the extreme, thus the resonance frequency, for example, is referenced with respect to numerous frequency ranges. The frequency ranges may differ in this case, such that they do not overlap with respect to the frequency values. As a result, the position of the extreme (frequency) can lead to unambiguous conclusions regarding the present operating state. As a result, a clear and unambiguous determination of the operating state of the circuitry, or the circuit section, respectively, may also be possible. Aside from the first operating state and the second operating state, the evaluation unit can, as a matter of course, also be designed to determine the presence of further operating states, to which frequency ranges have likewise been assigned.

Optionally, with a circuitry according to an exemplary embodiment, this circuitry can be designed to switch from the first operating state to the second operating state, and subsequently to switch from the second operating state to the first operating state. In other words, the circuitry and its components can be designed such that it enables a reversible switching between the first and second operating states. This can occur, for example, by means of the already explained reversible influencing of the circuitry components of the circuit section capable of oscillation in the circuitry. A circuitry according to such an exemplary embodiment can thus, if applicable, allow for not only the detection a simple switching of the operating state but rather, at least a multiple switching between the individual operating states. A circuitry according to an exemplary embodiment can thus enable, for example, multiple switchings between the operating states, without intervention in the form of maintenance or repairs.

Optionally, with a circuitry according to an exemplary embodiment, the evaluation unit can additionally or alternatively be designed to detect the occurrence of a malfunctioning state, deviating from an operating state of the circuit section, and to emit an error signal containing data regarding the presence of the malfunctioning state of the circuit section, when the malfunctioning state occurs. As a result, it may be possible to increase operational safety of the circuitry or the system comprising the circuitry, because, in the event of a malfunctioning state of the system, the circuitry is informed thereof. This can, for example, improve an operational safety in applications that are critical or relevant to safety, when the presence of the malfunctioning state has been registered. Such a malfunctioning state can, for example, impact the circuitry component itself. Thus, the possibility of distinguishing between a normal operating state and a malfunctioning state can be created.

Optionally, the evaluation unit in such an exemplary embodiment can be designed to determine the presence of the malfunctioning state when a maximum and/or minimum value of the detected signal strength fulfills a predetermined condition. As a result, it may also be possible to determine the presence of the malfunctioning state independently of a parameter that is a function of the frequency of the oscillation behavior. As a result, it may also be possible to detect a malfunctioning state that does not occur, or is only negligibly significant, or is at least insignificant, with respect to the frequency in the oscillation behavior.

The predefined condition can, for example, then be fulfilled when a threshold signal strength has been fallen short of or exceeded. A malfunctioning state can thus be distinguished, if applicable, from a normal operating state, and detected as such. Such a malfunctioning state can comprise a short circuit or a circuit interruption (load separation).

Additionally or alternatively, a circuitry according to an exemplary embodiment of the circuit section can comprise a diagnosis component that is designed to maintain an oscillation capability of the circuit section with a frequency of the extreme of the oscillation behavior that fulfills a predetermined further condition, even in the event of a short circuit or when the circuitry component has been bypassed. The evaluation unit can also be designed thereby to detect the presence of the malfunctioning state or a further malfunctioning state, when the predetermined further condition is fulfilled. It can optionally provide the error signal in this case, which comprises data regarding the presence of the malfunctioning state, or the further malfunctioning state, respectively. As a result, it may also be possible to detect such a malfunctioning state as such, in which, without the diagnosis component, an oscillation capability of the circuit section may no longer be present. As a result, it is also possible by this means to improve an operational safety of the circuitry, or a system comprising this circuitry, respectively.

The further condition can then be fulfilled, for example, when the frequency of the extreme exceeds and/or falls below a predetermined threshold frequency. Depending on the concrete design and the relevant signal, the diagnosis component can be connected in parallel or in series, for example, to the circuitry component.

In other words, by this means it may be possible to obtain that, even in the case of such a malfunction within the frequency range in which all frequencies of the numerous frequencies lie, an extreme exists and can be detected. A case of such a malfunction can—depending on the structural design of an exemplary embodiment—exist in the form of a short circuit or an interruption. The diagnosis component can be designed, for example, like the circuitry component, thus it can likewise be implemented as an inductive circuitry element, when the circuitry component is also implemented as an inductive circuitry element. The same applies equally for capacitive and resistive circuitry elements.

A circuitry according to an exemplary embodiment can furthermore comprise a further circuit section that is capable of oscillation, wherein the evaluation unit is also designed for determining a further oscillation behavior of the further circuit section through the sampling of the numerous predetermined frequencies. The evaluation unit can furthermore be designed to detect a change in a parameter of the circuit section through a comparison of the oscillation behavior with the further oscillation behavior. As a result, it may also be possible to attribute a change in the oscillation behavior to a change in a parameter of the circuit section, which may be assigned to an external influence, or an operating state, without implementing the further circuit section by the evaluation unit, which external influence or operating state would deviate from the actual present external influence or the actual present operating state of the circuitry. In other words, through the use of the further circuit section and the correspondingly designed evaluation unit, a determination precision regarding the external influence or a corresponding operating state may be improved. A corresponding change to a parameter of the circuit section can be attributed, for example, to a change in the operating parameter of the circuitry, thus, for example, to a change in the operating temperature, or to an aging of the components of the circuitry. The evaluation unit can, in such a case, optionally be furthermore designed to compensate, at least in part, or entirely, for an effect of the change in the parameter. In other words, the change to the parameter of the circuitry assembly may thus be a drift dependency within the circuitry, thus a temporal change, or a change to a parameter of a component or numerous components of the circuit section caused by another parameter.

As such, the further circuit section and the circuit section can be designed in a similar or even substantially identical manner, differing only in terms of the susceptibility of the circuit component to influences from the external influence. Depending on whether the further circuit section differs from the circuit section with respect to the circuit component and its susceptibility to influences from the external influence, the evaluation unit may detect a substantially constant further oscillation behavior, which is not, or at least not substantially, altered by the external influence. Alternatively, as a matter of course, the evaluation unit can also determine, more or less parallel to the oscillation behavior of the circuit section, the further oscillation behavior of the further circuit section, and thus execute, in parallel, a second determination of the external influence, and thus, if applicable, the operating state of the circuit.

Optionally, a circuitry according to an exemplary embodiment can furthermore comprise a rectifier section, which is coupled with the circuit section and designed such that it enables the evaluation unit to detect the respective signal strength of the circuit section that is a function of the amplitude of the oscillation of the circuit section at the relevant frequency of the numerous frequencies. As a result, it may be possible to implement a simpler detection of the signal strengths, and thus a simpler determination of the oscillation behavior. As a result, it may be possible on the whole to further improve a compromise between the performance capability of the circuitry, simple production and the implementation, if applicable. Depending on the concrete design, the rectifier section can be connected in parallel or in series with respect to the circuit section.

As a matter of course, in the case of a circuitry according to an exemplary embodiment in which a further circuit section is implemented, this too can be coupled to the evaluation unit via a further circuit section as well. This can be implemented substantially identically, but also differently, to the rectifier section of the circuit section.

A sensor according to an exemplary embodiment comprises a circuitry according to an exemplary embodiment, as well as a moving, at least partially electrically conductive actuator. The actuator is disposed and designed thereby such that an actuation thereof causes the external influence. As a result, the circuitry according to an exemplary embodiment can be capable of detecting a movement of the actuator. The circuitry according to an exemplary embodiment can enable, for example, a substantially contact-free detection of the movement of the actuator, by means of which a sensor according to an exemplary embodiment may exhibit a longer service life and/or a greater operational reliability thereby.

A sensor according to an exemplary embodiment, as well as a circuitry according to an exemplary embodiment can be used, for example, in a vehicle, e.g. a motor vehicle, a utility vehicle, agricultural machinery, construction machinery, or a similar vehicle or machine. Likewise, a sensor according to an exemplary embodiment as well as a circuitry according to an exemplary embodiment can be used in the framework of a keyboard or another user interface.

A method according to an exemplary embodiment for determining an oscillation behavior of a circuit section of a circuitry that is capable of oscillation comprises an influencing of a circuit component comprised in the circuit section by an external influence, such that the oscillation behavior of the circuit section is altered by the external influence. The method furthermore comprises a sampling of the oscillation behavior of the circuit section at numerous predetermined frequencies, in order to determine the oscillation behavior.

An exemplary embodiment furthermore comprises a program having a programming code for executing a method according to an exemplary embodiment, when the program runs on a programmable hardware component.

Electrical or other components are indirectly coupled to one another via a further component, or directly coupled to one another, such that they enable a signal exchange in which data is transferred between the relevant components. As such, the corresponding coupling can be implemented and realized, in sections or entirely, for example, electrically, optically, magnetically, or by means of wireless technology. The signals can be continuous, discrete, or, for example, they may comprise both types in sections, with respect to their value range as well as their temporal course. Thus, the signals can be analog or digital signals. A signal exchange can furthermore also occur via a writing or reading of data in a register or another memory location.

Exemplary embodiments shall be described and explained in greater detail below, with reference to the attached figures.

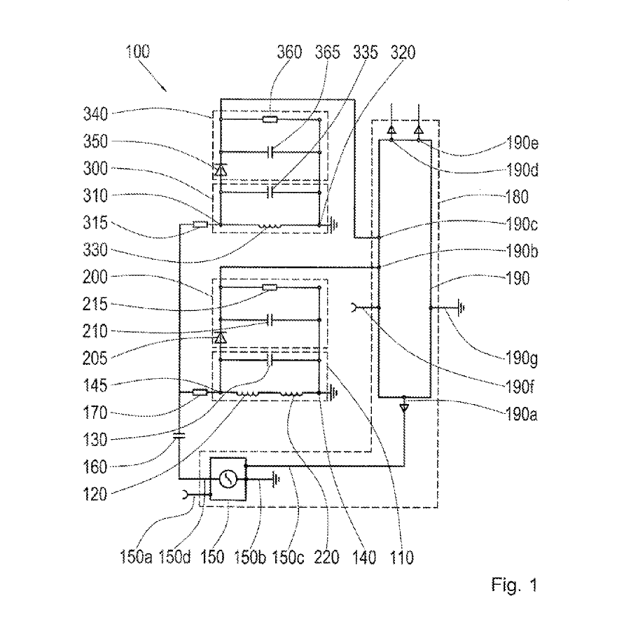

FIG. 1 shows a circuit diagram for a circuitry according to an exemplary embodiment;

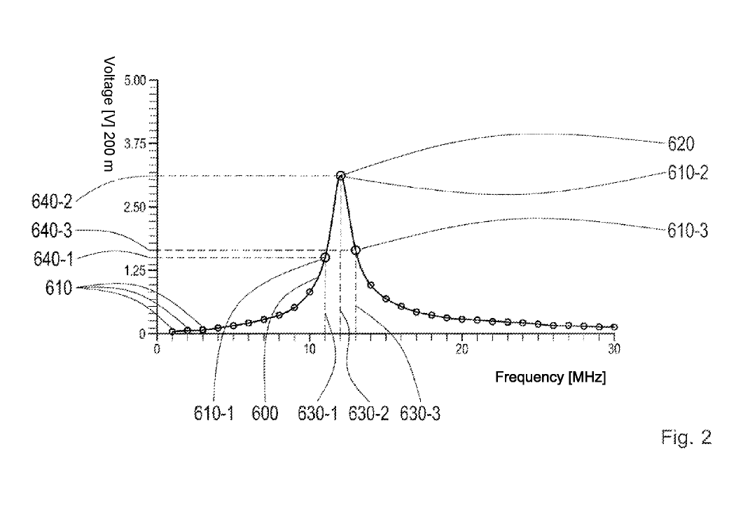

FIG. 2 shows a depiction of an oscillation course having numerous signal strengths disposed on frequencies of numerous frequencies;

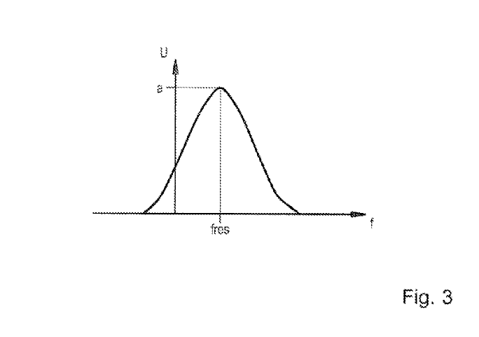

FIG. 3 shows a schematically simplified depiction of a resonance curve in the form of a bell curve;

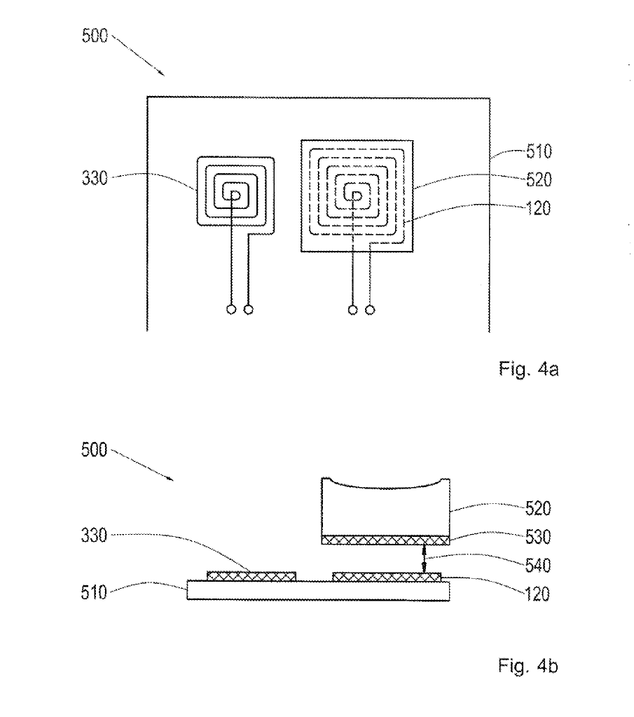

FIG. 4a shows a top view of a circuit component and a diagnosis component of a circuitry according to an exemplary embodiment;

FIG. 4b shows a side view of the circuit component shown in FIG. 4a, and the diagnosis component shown therein, as well as an actuator for a sensor according to an exemplary embodiment;

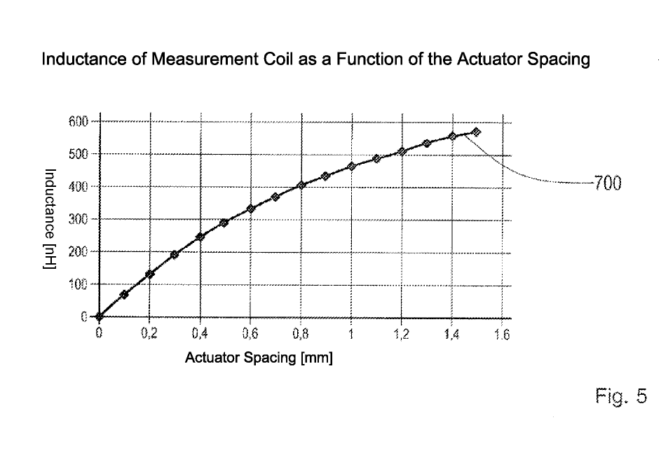

FIG. 5 illustrates a dependency of an inductance of a circuit component designed as a coil, as a function of a spacing to an actuator;

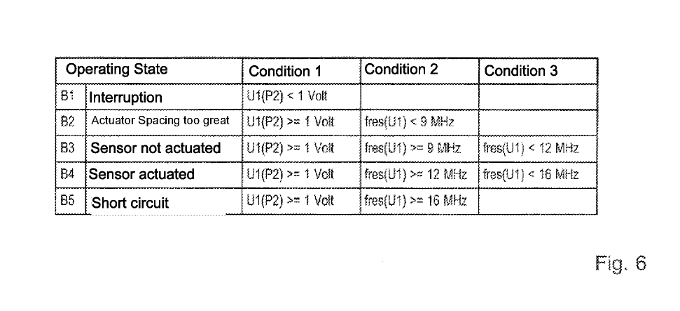

FIG. 6 shows a table with various operating states and malfunctioning states depending on numerous conditions;

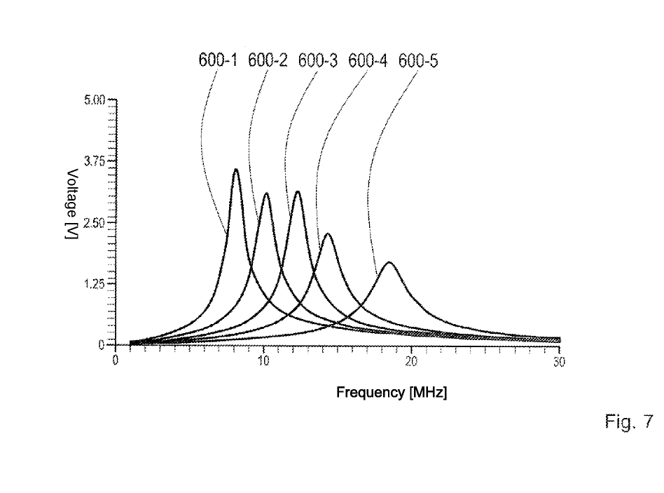

FIG. 7 shows a graphic depiction of numerous oscillation behaviors of a circuitry according to an exemplary embodiment, depending on different external influences; and

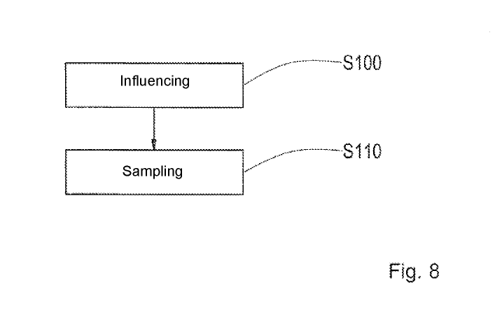

FIG. 8 shows a flow chart for a method for determining an oscillation behavior according to an exemplary embodiment.

In the following description of the attached figures showing the exemplary embodiments, identical or similar reference symbols indicate identical or comparable components. Furthermore, collective reference symbols are used for components and objects that occur multiply in an exemplary embodiment or in a drawing, but are described collectively with respect to one or more features. Components or objects that are indicated by identical, similar or collective reference symbols may have identical but also different designs regarding individual, numerous, or all features, such as their dimensions, for example, as long as nothing else is specified, explicitly or implicitly, in the description.

For safety critical applications in vehicles, but also in other technical fields, sensors are used having a high reliability and that should be capable of a diagnosis. This can frequently only be achieved with great difficulty using normal, conventional electrical contacts, because these contacts wear out and it is frequently the case that a diagnosis concerning the presence of a short circuit or an interruption can only be carried out with great difficulty. These criteria may be easier to fulfill with an inductive or capacitive design of a sensor.

Conventional solutions frequently require an individual calibration in this context. Moreover, they may exhibit a drift dependency, e.g. a temperature drift or an aging drift, or they may be subject to such. They may also exhibit a tolerance with respect to their hysteresis, as well as a comparably limited switching range. As the following description will show, exemplary embodiments may enable an improved compromise regarding production and implementation for such applications. As a result, it may be possible, for example, to provide inexpensive solutions for inductive sensors, but also for other applications. If applicable, a component expenditure may be reduced when, for example, an already existing microcontroller of a circuitry can be used. One exemplary embodiment, which shall be explained in greater detail below, thus enables a determination of an inductance that is a function of a sensor path that has been traveled as an evaluation method. Exemplary embodiments are partially based on the fact that these determine a high point, a low point or another extreme of a resonance curve, thus the oscillation behavior of a corresponding circuit section capable of oscillation. This evaluation method can potentially be implemented with a comparably limited temperature drift.

FIG. 1 shows a circuit diagram for a circuitry 100 according to an exemplary embodiment having an oscillating circuit section 110, which comprises a circuit component 120 that can be influenced. The circuit component 120 can be influenced by an external influence thereby, such that an oscillation behavior of the circuit section 110 can be altered by the external influence. The circuitry 100 is furthermore capable of determining the oscillation behavior of the circuit section 110 by a sampling at numerous defined frequencies.

In FIG. 1, the oscillating circuit section 110 is formed by an oscillating circuit, wherein the circuit component 120 is implemented as a coil in the exemplary embodiment shown here, which coil represents a portion of the oscillating circuit. The term “circuit section,” and “oscillating circuit section” and “oscillating circuit,” respectively, can thus be used synonymously in the context of the present exemplary embodiments. Furthermore, the oscillating circuit comprises an oscillating circuit capacitor 130 and a node 140, which is coupled to a reference potential, and is thus grounded. The circuit component 120 and the oscillating circuit capacitor 130 are coupled in parallel to one another between the node 140 and an input node 145.

The circuitry 100 shown in FIG. 1 furthermore comprises an optional frequency generator 150 that is designed to provide the circuit section 110 with the numerous defined frequencies. As a result, the numerous defined frequencies can thus be provided to the circuitry 100 independently of the oscillation behavior of the circuit section 110. Defined can thus mean that the frequencies have been previously selected, determined, or otherwise established. If applicable, they can also be changeable, by means of a programming or parameter set for example.

The frequency generator 150 is connected to a supply potential via a supply connection 150a, and to a further supply potential via a further supply connection 150b, which can be identical to the reference potential, for example. Thus, a supply voltage may be generated during operation between the supply potential on one side and the other supply potential, for example.

This is connected to the oscillating circuit section 110 via a coupling capacitor 160 and a coupling resistor 170. A voltage signal can be fed to the circuit section 110 via the coupling capacitor 160 here. By way of example, a coupling of a DC, or DC voltage signal (frequency 0 Hz) can be prevented by the coupling capacitor 160 for example, or at least significantly reduced, in order to thus reduce interfering effects to the signal that is to actually be detected, or to the frequency generator 150.

The frequency generator 150, as shown in FIG. 1, is designed thereby to provide a frequency signal at an output 150d, based on a frequency defining signal, which can be provided to the frequency generator 150 at the input 150c of the frequency generator 150. The frequency signal can exhibit a frequency thereby that is a function of a datum comprised in the frequency defining signal. In the case of a separate implementation of the frequency generator 150, the frequency generator can, for example, be a voltage controlled oscillator (VCO).

The circuitry 150 furthermore comprises an optional evaluation unit 180, which is coupled to the circuit section 110. It is capable of detecting, in each case, at least one signal strength of the circuit section 110 via its coupling to the circuit section 110 at the frequencies of the numerous defined frequencies. As shall be described in greater detail below, the voltage at the input node 145 of the circuit section 110 is detected via a rectifier section 200 thereby. The input node 145 is coupled to the coupling resistor 170 and the circuit component 120. The frequency generator 150 can be implemented here, fundamentally, as a part of, or external to, the evaluation unit 180.

With the exemplary embodiment shown in FIG. 1, the evaluation unit 180 comprises a programmable hardware component in the form of a microcontroller 190. The microcontroller 190 is provided with a supply potential via a supply connection 190f, and with a further supply potential, e.g. a reference potential (e.g. ground) via a further supply connection 190g. Thus, a supply voltage can be provided between the supply potential on one hand, and the further supply potential. An already existing microcontroller 190 can also be used here, for example, by means of which the component expenditure may also be reduced. The microcontroller 190 has a signal output 190a, by means of which a frequency defining signal can be provided to the frequency generator 150. The microcontroller 190 furthermore comprises a first analog/digital converter 190b (A/D converter), by means of which the aforementioned signal strength are applied to the input node 145 via the rectifier section 200 in the form of the voltage. As a result, the microcontroller 190 is able to detect said signal strengths.

In other exemplary embodiments, the frequency generator 150 can also be designed as a part of the microcontroller 190. In this case, this can result in a controllability of the frequencies emitted by the frequency generator 150, for example, based on an externally supplied clock signal, or an internally generated clock signal, using, for example, an analog or digital frequency divider. A digital frequency divider can be implemented, for example, on the basis of shift registers, while an analog frequency divider, for example, can be based on a circuitry for phase coupling. The frequency defining signal can be transmitted to the internally implemented frequency generator 150 in this case by writing a value in a memory space, a register for example.

The oscillating circuit section 110 is disposed downstream of the rectifier section 200, which comprises a rectifier diode 205. The rectifier diode 205 is incorporated between the input node 145 and the input assigned to the input of the first analog/digital converter 190b in the direction of passage. Thus, an anode of the rectifier diode 205 is coupled to the input node 145 and a cathode of the rectifier diode 205 is coupled to the input of the first analog/digital converter 190b.

The rectifier section 200 furthermore comprises a rectifier capacitor 210 as well as a rectifier resistor 215, which are coupled in parallel to one another with the cathode of the rectifier diode 205 on one hand, and the node 140 on the other hand. Collectively, they form an integrator, or low-pass filter, respectively, to which a semi-oscillation of the oscillation applied to the input node 145 that passes through rectifier diode 205, is supplied. The rectifier section 200 is thus capable of providing a signal to the evaluation unit 180 having a signal strength, which exhibits a dependence on an amplitude of the oscillation applied to the input node 145 defined by the configuration of the rectifier section 200. In other words, with the exemplary embodiment depicted here, the rectifier section 200 ensures that a voltage is applied at the input to the first analog/digital converter 190b, which exhibits a fully determined relationship to the amplitude of the oscillation at the input node 145.

Even when the signal strength corresponds to a voltage value in the exemplary embodiment of a circuitry 100 shown in FIG. 1, this can also comprise a current value in other exemplary embodiments. Likewise—depending on the concrete implementation of such a circuitry—the signal strength can also represent a differential or another stored parameter.

The evaluation unit 180 is furthermore designed to emit a signal, in the exemplary embodiment shown here, which comprises data regarding the presence of an operating state of the circuitry 100. This signal can be emitted from the microcontroller 190 to a circuit signal output 190d, for example.

The evaluation unit 180 in the exemplary embodiment shown here is furthermore capable of detecting a malfunctioning state of the circuit section 110 deviating from one of the operating states of the circuit 100, and to emit a corresponding error signal. This comprises data regarding the presence of the malfunctioning state of the circuit section 110, or the circuitry 100. A malfunctioning state of this type can occur, for example, as a result of a bypassing of the circuit component 120, if, for example, said component is short circuited.

One malfunctioning state or another malfunctioning state can, however, also consist, for example, of when an interruption of the current circuit occurs within the circuit section 110. Optionally, the evaluation unit 180 can be capable of detecting the presence of a malfunction when a signal strength, thus the voltage, exceeds or falls below a maximum or minimum value. If, for example, the voltage at the input node 145 increases or decreases strongly due to a connection interruption, the evaluation unit 180 can thus likewise detect a malfunction and emit a corresponding error signal.

In order to enable a detection of the malfunctioning state accompanying a short circuit of the circuit component 120 that is as reliable as possible, the circuit section 110 furthermore has an optional diagnosis component 220, which is designed to maintain the oscillation capability of the circuit section 110 even in the event of such a short circuit or another bypassing of the circuit component 120. The diagnosis component 220, which, in the case of the circuitry 100 shown here—as with the circuit component 120—is likewise an inductive component in the form of a coil, is designed and sized such that even in the event of the malfunction described here, the oscillation behavior exhibits a characteristic frequency, which can be distinguished in comparison to a corresponding characteristic frequency of one of the operating states. The characteristic frequency can be a frequency of an extreme thereby, for example, thus a maximum or minimum of the oscillation behavior, for example, which typically represents the resonance frequency of the relevant circuit section 110. In other words, this frequency fulfills a condition, from the presence of which, the evaluation circuit 180 can determine the presence of such a malfunction. The evaluation circuit 180 can then send a corresponding signal or error signal, for example, to a diagnosis signal output 190e of the microcontroller 190 shown in FIG. 1. The diagnosis component 220 and the circuit component 120 are connected to one another in series in the exemplary embodiment shown here.

The circuitry 100 shown in FIG. 1 furthermore has an optional oscillating further circuit section 300, which has a similar design to the circuit section 100, but in differing therefrom, only has an inductive circuit element. The further circuit section 300 is coupled to the frequency generator via a further input node 310. As with the input node 115 of the circuit section 110, the input node 310 here is connected to the frequency generator 150 via the coupling capacitor 160 and a further coupling resistor 315 corresponding to the coupling resistor 170.

On a side of the further circuit section 300 facing away from the coupling resistor 315, this circuit section has a further node 320, which—as with the node 140 of the circuit section 110—is connected to the reference potential, thus the ground, for example.

The further circuit section 300 as well as the coupling resistor 315 thus form a serial connection, as is also the case with the circuit section 110 and the coupling resistor 170. The two serial connections are in turn, for their part, coupled in parallel to one another between the reference potential and the coupling capacitor 160. Instead of the coupling of the further circuit section 300 to the frequency generator 150, this section can also be coupled to an optional further frequency generator 150.

The further circuit section 300 also has, internally, a parallel connection to a reference component 330 and a further oscillating circuit capacitor 335. The reference component 330 is similar thereby, with respect to its circuitry behavior, to the circuit component 120, such that the reference component 330 and the further oscillating circuit capacitor 335 collectively establish the oscillating capability of the further circuit section 300. The further circuit section 300 also represents an oscillating circuit in this manner, for which reason the term “further circuit section” and “further oscillating circuit” can be used synonymously for these. The reference component 330 is likewise implemented as an inductive circuit element in the form of a coil in the exemplary embodiment shown here, as is also the case with the circuit component 120 of the circuit section 110.

With the sizing of the reference component 330, as well as the further component or components of the further circuit section 300, numerous designs and boundary conditions may be taken into account. If, for example, comparable currents and voltages are to be present in the further circuit section 300 as those in circuit section 110, it may be advisable to size the reference component such that its impedance corresponds to that of the circuit component 120, or—if the diagnosis component 220 is implemented—to both. As a matter of course, a scaled implementation, or one that deviates therefrom, may also be used in exemplary embodiments.

The further input node 310 is coupled to the evaluation unit 180 via a connection of a second analog/digital converter of the microcontroller 190. By means of this coupling, the evaluation unit 180 is able to determine an oscillation behavior of the further circuit section 300, in that it detects, in turn, in the frequencies of the numerous frequencies, a further signal strength at the further input node 310. This is again a voltage that is characteristic for these frequencies, or is a value that is derived therefrom.

Thus, a rectifier is connected between the further input node 310 and the input of the second analog/digital converter 190c, the further rectifier section 340, which corresponds to the rectifier section 200 in terms of its fundamental design, but with regard to the sizes of its components, may differ entirely or in part from the rectifier section 200. As a matter of course, however, the rectifier sections 200, 340 can also be identical in size.

Thus, the further rectifier section 340 is connected to the further input node via a further rectifier diode 350, thus its anode, connected in the direction of passage. A cathode of the further rectifier diode 350 is connected to a further rectifier resistor 360 and a further rectifier capacitor 365 in a parallel connection. The further rectifier resistor 360 and the further rectifier capacitor 365 are connected to the reference potential via the further node 320.

The further rectifier capacitor 365 and the further rectifier resistor 360 thus form an integrator, or low-pass filter, respectively, by means of which a half-oscillation passing through the further rectifier diode 350 of the oscillation occurring at the further input node 310 during operation is flattened, or integrated, respectively. As a result, a signal strength in the form of a voltage value—as a function of the respective frequency of the numerous frequencies, for example—can be detected by the evaluation unit 180, which exhibits a fully determined dependency on the amplitude of the oscillation at the further input node 310.

The further rectifier section 340 and the further circuit section 300 are optional components of the circuitry 110, as it is shown in FIG. 1, and can be omitted, for example, in other exemplary embodiments. This fundamentally applies to the rectifier section 200 as well. The rectifier sections 200, 340 can also be designed differently, independently of one another, insofar as they are implemented and provided for at all.

As such, with the exemplary embodiment shown here, the evaluation unit 180 is also capable of determining the further oscillation behavior of the further circuit section 300 by sampling the numerous defined frequencies. By comparing the oscillation behavior of the circuit section 110 with the further oscillation behavior of the further circuit section 300, the evaluation unit can thus determine a change in one or more of the parameters of the circuit section 110, thus, for example, a drift resulting from an operating parameter (e.g. temperature) or due to aging. Thus, the further circuit section 340 can be used, if applicable, for compensating for, or taking into account, a temperature, aging or some other parameter drift, which in turn, can contribute to an improvement in the determination precision.

Assuming that a suitable sizing is achieved, then it is possible, for example, through the described parallel connection, that identical or comparably signal strengths may be present at the two input nodes 145, 310, if, for example, there is no, or only an insignificant, parameter drift present. In other words, identical or comparable voltage drops may occur in the two circuit sections 110, 340 in the case of a suitable sizing and comparable operational, aging and other parameters.

Even when, with the exemplary embodiment of a circuitry 100 shown here, a parameter that is a function of the potential at the input node 145 (or a voltage present in relation to the reference potential, respectively) is used as the signal strength, with other exemplary embodiments, as a matter of course, another signal strength may be used. Thus, a current strength or a valued derived therefrom can also be used, for example. This likewise applies to the further signal strengths with respect to the further circuit section 300, insofar as this is implemented.

With the exemplary embodiment shown here, the evaluation circuit 180 includes the microcontroller 190, which plays a central role as a programmable hardware component in this exemplary embodiment regarding activation and detection of the signal strengths. Before, however, the further functioning of the circuit 100 is to be described in greater detail, it should be noted that with other exemplary embodiments, such a central role of a microcontroller or another programmable hardware component is not necessary. Thus, for example, instead of a programmable hardware component that is designed as a discrete component, a construction using numerous discrete components can also be used. These can be disposed, for example, spatially distributed on a printed circuit board or a similar carrier. It is also not at all necessary to make use of an implementation based substantially on digital technology. Exemplary embodiments can likewise be entirely or at least partially based on the use of analog circuit technology with respect to the evaluation unit 180 and/or other potential components.

With the exemplary embodiment shown here, the microcontroller 190 is configured such that it can activate the frequency generator 150. For this purpose, the microcontroller 190 provides the frequency generator with a frequency defining signal via the signal output 190a and the input 150c, which, for example, comprises data regarding the temporal sequence and the frequencies that are to be provided by the frequency generator 150.

With the circuitry 100 shown here, the frequency defining signal can comprise—in the case of an analog implementation of the frequency generator 150 as a VCO—a temporal sequence of voltage values, which correspond to the frequencies that are to be activated, in the frequency range of 0 MHz to 30 MHz, for example. The exemplary embodiments and examples described below are based on an equidistant distribution of the frequencies—in terms of the frequency—having a step width of 1 MHz.

The frequency generator 150 makes a corresponding frequency signal available with such a cycle, which can optionally be repeated once, or more frequently, via the coupling capacitor 160 and the coupling resistors 170, 315 of the circuit section 110 and the further circuit section 300. As a result, there is a voltage at the input nodes 145, 310, which is made available to the microcontroller 190, and thus the evaluation circuit 180, via the rectifier sections 200, 340, in order to thus be able to determine the oscillation behavior of the circuit section 110, and—if applicable—the further oscillation behavior of the further circuit section 300. In other words, the voltages at the input nodes 145, 310 are rectified by the rectifier sections 200, 340, and subsequently measured and stored by the microcontroller 190 for each frequency step.

For this, the detected signal strengths or voltages, for example, can be assigned to the respective frequencies provided by the frequency generator 150, and accordingly stored in a memory of the microcontroller 190. This can be in the form of a table, a classification, a matrix, an array, or some other form, for example. An appropriate classification can also be distributed, indexed, or stored in some other manner, over numerous memories. An evaluation, determination and/or classification of this frequency/voltage classification can occur, for example, at the end of the frequency cycle.

The circuitry 100, as shown in FIG. 1, can then be used to determine an external influence that acts on the circuit component 120 such that the oscillation behavior of the circuit section 110 is altered. This can occur, as shall be explained in greater detail below, by way of example, in the context of FIGS. 4a and 4b, through a change in the inductance of the coil serving as the circuit component 120. With the exemplary embodiment of a sensor described there, this is achieved when a metal coating is approached, which is disposed on an end of an actuator facing toward the circuit component 120, and thus resulting in a change in the inductance.

With other exemplary embodiments, the external influence can also act on the circuit component 120 in a different manner, when this is not designed as an inductive circuit element, for example. Thus, the circuit component 120 can also be designed as a capacitive circuit element, thus, for example, as a capacitor. In this case, the change in the oscillation behavior of the circuit section 110 can be caused, for example, through a change in the capacitance value of the capacitive circuit element. This can be caused, for example, through the introduction of a dielectric medium, or a change in a spacing between two electrodes of the capacitive circuit element, when, for example, the metal coating specified above represents an electrode of the capacitive circuit element. The circuit component 120 can also be implemented, however, as a resistive circuit element, the resistance value of which, and thus its impedance, changes, for example, due to a mechanical deformation or a thermal effect. In other words, the resistive circuit element can be designed as a resistive bending sensor (e.g. strain gauges).

In other words, with the circuitry 100 shown here, a microcontroller 190 is used for controlling the frequency generator 150, which can emit a voltage having a frequency of approx. 0 MHz to approx. 30 MHz, for example. The frequency generator can also be integrated in the microcontroller 190. The frequency is swept through in short time intervals in approx. 1 MHz steps from approx. 0 MHz to approx. 30 MHz, and then starts from the beginning again. The voltage of the frequency generator 150 is fed into the two circuit sections 110, 300 via the coupling capacitor 160 and the resistors 170, 315. Rectifiers 200, 340 are disposed downstream thereof. The rectified voltages are measured by the microcontroller 190 at each frequency step, and then stored in arrays, for example. The evaluation of the frequency/voltage array and classification occurs, for example, at the end of the frequency sweep. The sensor setting (actuated, not actuated) can be transmitted at the circuit signal output 190d. Error data (interruption, short circuit, actuation spacing too great) can be emitted at the diagnosis output 190e.

The circuit section 110 comprises the measurement coil 120, which can be attached to the printed circuit board as a planar coil, a diagnosis coil 220, which can be designed as an SMD coil, and the oscillation circuit capacitor 130. The diagnosis coil 220 can be used to be able to detect a short circuit in the measurement coil 120. As a result, there is a high resonance frequency here, because only the diagnosis coil 220 and the oscillation circuit capacitor 130 are still used to determine the oscillation circuit frequency. The sensor path can be measured with the oscillation circuit S1. With numerous sensors, numerous identically or differently constructed oscillation circuits can be provided.

The further circuit section 300 comprises the reference coil 330, which can be designed as a planar coil attached to the printed circuit board, or as an SMD coil, and the oscillation circuit capacitor 335. The reference coil 330 is not affected by an actuator. A possible thermal drift or aging drift of the circuitry 110 can potentially be compensated for with the further circuit section 300. If necessary or desired, this oscillation circuit can also be built up twice, or more times, e.g. once with a coil having a low inductance, and once with a coil having a higher inductance, in order to be able to implement a linear compensation therewith.

FIG. 2 shows an exemplary oscillation behavior 600 as a curve of the detected, or detectable, signal strengths—here the detected or detectable voltage—as a function of the frequency. FIG. 2 shows furthermore, individual detected signal strengths in the form of measurement points 610, each of which corresponds, or is assigned, to a frequency of the numerous defined frequencies and a corresponding signal strength. In FIG. 2, the oscillation behavior 600 is also indicated at frequencies to which none of the frequencies of the numerous frequencies are assigned, and which are thus potentially not detected in a corresponding cycle. FIG. 2 thus shows the oscillation behavior 600 of the circuit section 110 as a curve, as well as in the form of exemplary measurement points 610 that are detected in the curve, accordingly. Errors and measurement inaccuracies remain unaccounted for here, even though they may, however, lead to a deviation.

As a result of the numerous defined frequencies being able to be provided independently of the oscillation behavior 600 of the circuit section 110, a systematic approach, independent of the external influence, can now be implemented.

As has already been explained, the evaluation unit 180 is capable of determining the oscillation behavior 600. This can be achieved by the evaluation unit in that it determines an extreme 620 of the oscillation behavior 600 based on the detected signal strengths. The extreme 620 of the oscillation behavior 600 is a maximum occurring voltage value in FIG. 2, which lies at approx. 12 MHz in FIG. 2.

The extreme 620 can then be determined based on numerous measurement points 610. If the numerous frequencies comprise at least three frequencies, specifically the first frequency 630-1, a second frequency 630-2, and a third frequency 630-3, of which the second frequency lies between the first and the third frequencies 630-1, 630-3, then the signal strength values 640-1, 640-2, 640-3 assigned to the relevant frequencies 630-1, 630-2, 630-3 can be referenced for the evaluation and determination. Thus, in the region of the extreme 620, the signal strength value lies above the other signal strength values 640. If, for example, the evaluation unit 180 finds a signal strength value 640, in the present case the second signal strength value 640-2 (measurement point 610-2) assigned to the second frequency 630-2, that lies above the signal strength values 640-1, 640-3 (measurement points 610-1, 610-3) assigned to the two adjacent frequencies 630-1, 630-3 on both sides thereof, on the frequency axis, then this evaluation unit can determine the extreme 620 from this, and can thus determine the position of the resonance frequency of the circuit section 110. The extreme determined in this manner may, potentially, deviate from the actual extreme of the oscillation behavior 600. In other words, this determination may be erroneous.

In FIG. 2, the first frequency 630-1 is approx. 11 MHz, the second frequency 630-2 is approx. 12 MHz, and the third frequency 630-3 is approx. 13 MHz. The evaluation unit 180 can use an interpolation, for example, in order to improve the precision and thus to reduce errors in the determination.

One method of interpolation shall be explained in greater detail by way of example, wherein, however—depending on the computing power of the evaluation unit 180—more complex methods can also be used, based, for example, on a minimizing of error squares.

In order to now, for example, be able to determine an external influence, thus, for example, a change in an actuator spacing, the resonance frequency fᵣₑₛ of the extreme 620 can be interpolated from the frequency/voltage relationship, or the oscillation behavior 600, respectively, shown in FIG. 2, and thus estimated or calculated. The values of the greatest signal strength 640-2, thus the second signal strength 630-2 (U₂), and the two adjacent values, the first signal strength 640-1 (U₁) and the third signal strength 640-3 (U₃) are sought in the frequency/voltage relationship, and entered into the equation:

fᵣₑₛ=f₂+df*(ln(U₃)−ln(U₁))/(2*(2*ln(U₂)−ln(U₁)−ln(U₃)))

df indicates the spacing between two adjacent frequencies here (df=f₂−f₁=f₃−f₂), when these are equidistant—as described above—for example, ln( ) indicates the natural logarithm thereby.

Expressed in general, the calculation of the resonance frequency fᵣₑₛ is based on a sum of the second frequency 630-2 (f₂) and a product of the spacing between two adjacent frequencies (df) and the difference of two values that are functions of the first signal strength 640-1 and the third signal strength 640-3, divided by the difference from the difference of two values that are a function of the second signal strength 640-2 and the first signal strength 640-1, and from the difference of two values that are functions of the third signal strength 640-3 and the second signal strength 640-1. The coil inductance L₁ of the circuit component 120 can then be calculated from the resonance frequency fᵣₑₛ, wherein C₂ is the capacitance value of the oscillation circuit capacitor 130, and L₂ is the inductance of the diagnosis component 220:

L₁=(1/2π*fᵣₑₛ)*(1/C₂)−L₂

By entering, or a comparison of, the values determined in this manner, the inductance L₁ of the circuit component 120 in the diagram shown in FIG. 5, described below, the external influence can thus be determined, thus, for example, the spacing to the already mentioned actuator.

The evaluation method described herein can be derived as follows.

A signal, in this case in the form of a voltage signal, is depicted in FIG. 2. The frequency of the signal can be increased thereby in steps of 1 MHz from approx. 0 MHz to 30 MHz. At each frequency increase, a signal strength, thus a voltage here, can be measured and entered as a measurement point 610 in the diagram shown in FIG. 2. By placing a polygonal line through the measurement points 610, a typical bell curve is obtained, for example, which assumes its maximum, thus its extreme 620 at the resonance frequency fᵣₑₛ. The bell curve follows the equation:

U=a*exp(−b*(f−fᵣₑₛ)²)

wherein a and b are real constants and exp( ) is the exponential function.

A curve of this type is shown by way of example in FIG. 3. f is the frequency thereby, U is the voltage, fᵣₑₛ is the resonance frequency, thus the frequency at the maximum or apex (extreme 620), a is the voltage at the apex, and b is the width (half width) of the bell curve.

The resonance frequency fᵣₑₛ can then be calculated or approximated as follows.

Because the equation of the bell curve 3 comprises unknowns (a, b, fᵣₑₛ), three equations may be formulated for calculating the parameter fᵣₑₛ. Furthermore, three frequency voltage value pairs are needed, such as those already presented above in the form of the three measurement points 610-1, 610-2, 610-3, or their frequencies 630-1, 630-2, 630-3 (f₁, f₂, f₃) and their signal strength values 640-1, 640-2, 640-3 (U₁, U₂, U₃). From the equation system:

U₁=a*exp(−b*(f₁−fᵣₑₛ)²)

U₂=a*exp(−b*(f₂−fᵣₑₛ)²)

U₃=a*exp(−b*(f₃−fᵣₑₛ)²)

and the given, that the spacings of the frequencies at the three points, which correspond to the three frequency voltage value pairs, are the same size (df=f2−f₁=f₃−f₂), after solving the equation system, one can obtain the equation for calculating the resonance frequency from the three value pairs:

fᵣₑₛ=f₂+df*(ln(U₃/U₁))/(2*(ln(U₂)²/U₁*U₃)))

or

fᵣₑₛ=f₂+df*(ln(U₃)−ln(U₁))/(2*(2*ln(U₂)−ln(U₁)−ln(U₃)))

The determination of the three value pairs occurs here over the value with the maximum signal strength, thus the maximum voltage in this case. This maximum voltage is assigned to the value U₂, and the frequency f₂. The value pairs (f₁, U₁) and (f₃, U₃) are the two values adjacent to the value pair (f₂, U₂). The voltages U₁ and U₃ are lower than the voltage U₂ thereby.

In FIG. 2, the first value pair comprises, for example, the first frequency 630-1, having a value of approx. 11 MHz, as well as the first signal strength 640-1, having a value of approx. 1500 mV. The second value pair comprises the second frequency 630-2, having a value of approx. 12 MHz, and the second signal strength 640-2, having a value of approx. 3125 mV. The third value pair comprises the third frequency 630-3, having a value of approx. 13 MHz, as well as the third signal strength 640-3, having a value of approx. 1625 mV.

The difference of the second frequency 630-2 and first frequency 630-1 is approx. the same as the difference of the third frequency 630-3 and the second frequency 630-2, and has a value of approx. 1 MHz. According to the preceding equation for determining the resonance frequency fᵣₑₛ, a resonance frequency is obtained therefrom of approx. 12.0289 MHz. The derivation of the evaluation method, as well as the calculating of the resonance frequency represent only examples herein, as a matter of course. Other methods can certainly be used as well for the derivation, determination and evaluation.

FIG. 4a shows a schematic, simplified view of a printed circuit board 510 for a circuitry 100, as it can be used, for example, in the framework of a sensor 500. FIG. 4b shows a corresponding side view of the printed circuit board 510 for the sensor 500. The circuitry 100 of the sensor 500 is depicted only in part in FIGS. 4a and 4b. All, some, or only one of the components of the circuitry 100 can be disposed and attached thereto.

More precisely, one or more planar coils are attached to the printed circuit board 510 shown in FIGS. 4a and 4b, which can serve as a circuit component 120 (measurement coil) and—if applicable—as a reference component 330 (reference coil) or even as a diagnosis component 220. The inductances can be determined with the circuitry 100 that has already been described above in reference to FIG. 1. Aside from planar coils, the circuit elements of the circuitry 100 can also be attached using other technologies, e.g. as SMD components (Surface Mounted Device).

An actuator is moveably disposed on the top, perpendicular to a surface of the printed circuit board, on a side of the printed circuit board 510 facing toward the circuit component 120. This has a metallic, or electrically conductive coating 530 on a side facing the circuit component 120.

If the actuator 520 is then moved, thus a spacing between the actuator 520 and the circuit component 120, also referred to as the actuator spacing 540, is altered, then the inductance of the circuit component 120 changes due to the electrically conductive coating 530 on the actuator 520. As a result, the resonance frequency of the circuit section 110 is altered and thus its oscillation behavior 600.

Thus, if one moves the actuator 520 having the metallic, conducting undersurface (530), which can be made, for example, from copper or another metallic and/or electrically conductive material, toward the coils (circuit component 120 and reference component 330), their inductances change, by means of which a sensor function can be detected. More precisely, the inductances decrease in the case shown here.

FIG. 5 shows a depiction of a function 700 of the inductance L₁ for the coil serving as the circuit component 120 as a function of the actuator spacing 540. As has already been explained, the inductance L₁ decreases as the actuator spacing 540 decreases.

Thus, an external influence acts on the circuit component 120. The position of the actuator 520, thus whether this is actuated or not actuated, can be output at the circuit signal output 190d of the microcontroller. In the event of a malfunction state, thus, for example, the presence of an interruption or a short circuit, this can be indicated at the diagnosis signal output 190e by the microcontroller 190 through the provision of a corresponding signal (error signal).

Depending on the concrete implementation, the external influence may act on the reference component 330, or it may not have an effect thereon, if a further circuit section 300 is provided. If the external influence is not active with respect to the reference component 330, for example, then by this means a possible temperature or aging drift dependency of the circuitry 100, for example, can be detected, and thus compensated for. As a matter of course, numerous further circuit sections 300 can be implemented, having different further oscillation behaviors, for example, that are not altered by the external influence. As a result, a linear compensation for a drift dependency can be achieved, if applicable.

As has already been explained above, the diagnosis component 220 can be used to detect a short circuit of the circuit component 120, in which case the resonance frequency increases here, because the oscillation circuit frequency in this case, regarding the inductance, is substantially determined by only the diagnosis component 220 and the oscillation circuit capacitor 130.

Optionally, the evaluation unit 180 can also be capable of determining the presence of a malfunction when a signal strength, thus the voltage, has exceeded or fallen below a maximum or minimum value, for example. This type of error recognition shall be explained below.

An operating state of the circuitry 100, or the sensor 500 can, as explained above, determine an operating state from the position of the resonance frequency, thus the position of the extreme 620. This can occur such that frequency ranges are defined, for example, that are assigned to individual operating states. If the frequency of the extreme lies in such a frequency range, then the evaluation unit 180 will assume the presence of the relevant operating state. Due to the design of the circuitry, this can also occur in reverse. It is thus possible to change from a first operating state, corresponding, for example, to the sensor 500 not being pressed, to a second operating step, corresponding to the pressed sensor 500. Subsequently, the sensor 500 can change back to the first operating state. The same also applies, if applicable, for other circuits 100 in accordance with an exemplary embodiment.

FIG. 6 shows a table listing the various operating state in a first column, as well as various frequency ranges assigned to these operating states, which are listed in the third and fourth columns, respectively, and labeled as “Bedingung 2” and “Bedingung 3” [“Condition 2” and “Condition 3”]. The predefined further condition referred to above is located in the second column, when an interruption is determined in the present exemplary embodiment, and is listed in the second column and labeled as “Bedingung 1” [Condition 1].

In the example shown in FIG. 6, the predefined further condition is a condition of the signal strength, more precisely, of the voltage value applied to the input node 145. If this value is less than 1 V, as the predefined threshold value, an interruption is determined (operating or error state B1).

Aside from the operating states B2, B3, B4 listed here, in which frequency intervals are defined via the columns 3 and 4, the table also comprises the further malfunctioning state B5. The operating states indicated by B2, B3 and B4 are operating states thereby that may occur routinely, and are assigned to a setting of the actuator 520 to the circuit component 120.

If, however, a short circuit occurs (operating or error state B5), then this error state can be determined in the case shown here, due to the very high resonance frequency, lying above a limit of 16 MHz. This limit frequency is determined, regarding the inductance, substantially from the diagnosis component 220.

FIG. 7, lastly, shows various oscillation behaviors 600-1, . . . , 600-5 of the circuit section 110 in five different operating or error states, as a function of the frequency. Voltage values are plotted on the y-axis, and frequency values are plotted on the x-axis.

The table in FIG. 6 can be used for the evaluation, for example. The first curve 600-1 thus shows a maximum lying below a limit frequency of 9 MHz, based on which the presence of the operating step B2 may be assumed (actuator spacing 540 is too great). The second curve 600-2 has a maximum in a frequency interval between 9 MHz and 12 MHz, based on which it follows that the sensor 500 is presently in the operating state B3 (sensor not actuated). The third curve 600-3 gives the further oscillation behavior of the further oscillating circuit section 300 as the reference. The fourth curve 600-4 comprises a maximum in an interval between 12 MHz and 16 MHz, based on which the presence of the operating state B4 (sensor actuated) can be determined. The fifth curve 600-5 has a maximum value at a frequency lying above 16 MHz, based on which the operating state, or error state, B5 (short circuit) can be assumed.

The first curve 600-1 and the fifth curve 600-5 represent various malfunctioning states here, while the second curve 600-2 and the fourth curve 600-4 are each assigned to an operating state.

The oscillating circuit section 110 can thus be used for measuring or determining a sensor pathway (spacing of the actuator to the circuit section 120) for example. With exemplary embodiments, it is thus fundamentally possible to have numerous sensors on a printed circuit board 510, and optionally, comprise numerous circuit sections 110, for example, having substantially identical designs, or different designs.

FIG. 8 shows, lastly, a flow chart for a method for determining an oscillation behavior 600 of an oscillating circuit section 110 of a circuitry 100. In the framework of an effect S100 on a circuit component 120 comprised in the circuit section 110 by an external influence, the oscillation behavior 600 of the circuit section 110 is thus altered by the external influence. By sampling S110 the oscillation behavior 600 of the circuit section 110 at a plurality of defined frequencies, the oscillation behavior 600 can thus be determined. As a matter of course, these and other method procedures can also occur in other sequences, temporally overlapping, or temporally sequential.

Thus, with one exemplary embodiment, the inductance, or the sensor pathway, respectively, can be determined with great precision, for example, with the described evaluation method, in comparison with a method for a simple mechanical contact system. Furthermore, the shown evaluation method can enable, if applicable, the apex (extreme) of the resonance curve to be located with likewise comparatively high precision. The switch point can thus likewise be locatable, independently of the resonance curve, if applicable. It may also be possible with the evaluation method to reduce a temperature drift dependency.

The oscillating circuit section 110 can be used for measuring the sensor pathway (spacing of the actuator to the circuit component 120). Any number of sensors, or actuators, can fundamentally be evaluated with respect to their movement in exemplary embodiments, using a circuitry according to an exemplary embodiment, as long as there are sufficient analog/digital converters (AD converter) available in the framework of a microcontroller or another programmable hardware component. A square wave signal may already be sufficient as the frequency signal of a corresponding inductive evaluation circuit, which can be provided, for example, as a clock signal. If the signal can be emitted directly at a digital output (port) of a microcontroller, the use of an additional frequency generator can be eliminated. If, however, it is not possible to generate the frequencies with sufficient stability, because, for example, no quartz, or no other appropriate stable oscillation circuit is available, then these frequencies may be generated using an RC oscillator, if applicable. If these frequencies should exhibit a high drift or another corresponding deviation regarding a parameter, it may be possible to compensate for this through one, two or more reference coils, if applicable.

The features disclosed in the preceding description, the following claims and the attached figures may be of importance, and implemented, in and of themselves as well as in any combination for the implementation of an exemplary embodiment in its various designs.

Although some aspects are described in the context of a device, it is to be understood that these aspects also represent a description of the corresponding method, such that a block or a component of a device can also be understood as a corresponding method step or as a feature of a method step. Analogously, aspects that have been described in conjunction with a method step, or as a method step, also represent a description of a corresponding block or detail or feature of a corresponding device.

Depending on the determined implementation requirements, exemplary embodiments of the invention can be implemented in hardware or software. The implementation can be executed using a digital storage medium, e.g. a floppy disk, a DVD, a Blu-Ray disc, a CD, an ROM, a PROM, an EPROM, and EEPROM, or a flash drive, a hard drive, or another magnetic or optical memory, on which electronically readable control signals are stored, which can or do interact with a programmable hardware component such that the respective method is executed.

A programmable hardware component can be formed by a processor, a computer processor (CPU), a graphics processor (GPU), a computer, a computer system, an application-specific integrated circuit (ASIC), an integrated circuit (IC), a system on chip (SOC), a programmable logic element, a digital signal processor (DSP), or a field programmable gate array with a microprocessor (FPGA).

The digital storage medium can thus be computer or machine readable. Some exemplary embodiments thus comprise a data storage medium having electronically readable control signals, which are capable of interacting with a programmable computer system or a programmable hardware component, such that one of the methods described herein is executed. One exemplary embodiment is thus a data storage medium (or a digital storage medium, or a computer readable medium), on which the program for executing on of the methods described herein is recorded.

In general, exemplary embodiments of the present invention can be implemented as programs, firmware, computer programs or computer program products having a programming code, or as data, wherein the programming code or the data is, or are, effective in executing one of the methods, when the program runs on a processor or a programmable hardware component. The program code or the data can also be stored, for example, on a machine readable medium or data storage medium. The program code or the data may exist as, among other things, source code, machine code or byte code, as well as other intermediate languages.

Another exemplary embodiment is also a data stream, a signal sequence or a sequence of signals, which represent the program or programs for executing one of the methods described herein. The data stream, the signal sequence, or the sequence of signals can be configured in this respect, for example, to be transferred via the Internet or another network, for example, via a data communication connection. Exemplary embodiments are thus also signal sequences that represent data that are suitable for transfer via a network or a data communication connection, wherein they represent the data of the program.

A program according to an exemplary embodiment can implement one of the methods during its execution, for example, in that it reads out memory locations, or writes therein a datum, or data, by means of which, if applicable, switching procedures, or other procedures, can be triggered in transistor structures, in amplifier structures, or in other electrical, optical, or magnetic components, or components functioning according to another principle. Accordingly, through reading a memory location, a datum, value, sensor value, or other type of datum can be registered, determined, or measured by a program. A program can thus register, determine or measure parameters, values, measurement values and other data through a reading of one or more memory locations, as well as trigger, cause or execute an action through a writing in one or more memory locations, as well as activate devices, machines and components, and thus, for example, also execute more complex method steps by means of actuators.

The exemplary embodiments described above merely represent an illustration of the principles of the present invention. It is to be understood that modifications and variations of the assemblies and details described herein will be clear to other persons skilled in the art. For this reason, it is intended that the invention is limited solely by the scope of protection for the most relevant patent claim, and not by the specific details that are presented here through the description and explanations of the exemplary embodiments.

### REFERENCE SYMBOLS

100 circuitry
110 oscillating circuit section
120 circuit component
130 oscillation circuit capacitor
140 node
145 input node
150 frequency generator
150a supply connection
150b further supply connection
150c input
150d output
160 coupling capacitor
170 coupling resistor
180 evaluation unit
190 microcontroller
190a signal output
190b first analog/digital converter
190c second analog/digital converter
190d switch signal output
190e diagnosis signal output
190f supply connection
190g further supply connection
200 rectifier section
205 rectifier diode
210 rectifier capacitor
215 rectifier resistor
220 diagnosis component
300 further circuit section
310 further input node
315 coupling resistor
320 further node
330 reference component
335 further oscillation circuit capacitor
340 further rectifier section
350 further rectifier diode
360 further rectifier resistor
365 further rectifier capacitor
500 sensor
510 printed circuit board
520 actuator
530 electrically conductive coating
540 actuator spacing
600 oscillation behavior
610 measurement point
620 extreme of the oscillation behavior
630 frequency
640 signal strength
700 dependency
S100 influencing
S110 sampling

1. A circuitry having at least one oscillating circuit section, wherein the circuit section comprises:
a circuit component configured to be affected by an external influence, such that an oscillation behavior of the circuit section can be altered by the external influence, wherein the circuitry is also configured to determine the oscillation behavior of the circuit section by sampling a plurality of defined frequencies.

2. The circuitry according to claim 1 configured to provide the plurality of defined frequencies independently of the oscillation behavior of the circuit section.

3. The circuitry according to claim 1, further comprising a frequency generator configured to provide the plurality of defined frequencies to the circuit section.

4. The circuitry according to claim 1, further comprising an evaluation unit coupled to the circuit section, wherein the evaluation unit is configured to detect, via the coupling, at least one signal strength of the circuit section, in each case, at frequencies of the plurality of defined frequencies.

5. The circuitry according to claim 4, wherein the evaluation unit is configured to determine an extreme of the oscillation behavior based on the detected signal strengths.

6. The circuitry according to claim 5, wherein the plurality of defined frequencies comprise at least one first frequency, one second frequency and one third frequency, wherein a second signal strength at the second frequency is different than a first signal strength at the first frequency and a third signal strength at the third frequency, wherein the first frequency is lower than the second frequency, and the third frequency is higher than the second frequency, wherein the evaluation unit is configured to determine the extreme of the oscillation behavior through interpolation, based at least on the first signal strength, the second signal strength and the third signal strength.

7. The circuitry according to claim 5, wherein a first operating state is assigned to a first frequency range, and a second operating state is assigned to a second frequency range, and the evaluation unit is configured to determine, based on the presence of the first operating state or the second operating state, when a frequency of the extreme lies in the frequency range assigned to the operating state.

8. The circuitry according to claim 7, wherein the evaluation unit is configured to provide a signal containing information regarding the presence of the first or second operating state.

9. The circuitry according to claim 7, wherein the circuitry is configured to switch from the first operating state to the second operating state, and subsequently from the second operating state to the first operating state.

10. The circuitry according to claim 5, wherein the evaluation unit is configured to determine a presence of a malfunctioning state of the circuit section deviating from an operating state, and to emit an error signal containing information regarding the presence of the malfunctioning state of the circuit section.

11. The circuitry according to claim 10, wherein the evaluation unit is configured to determine the presence of the malfunctioning state when a maximum or a minimum value of the detected signal strength fulfills a predetermined condition.

12. The circuitry according to claim 10, wherein the circuit section further comprises a diagnosis component configured to maintain an oscillating of the circuit section with a frequency of the extreme of the oscillation behavior in the event of a short circuit or a bypass of the circuit component, such that the frequency of this extreme fulfills a predetermined further condition, and wherein the evaluation unit is configured to determine the presence of the malfunctioning state or another malfunctioning state when the predetermined further condition is fulfilled.

13. The circuitry according to claim 4, further comprising a further oscillating circuit section, wherein the evaluation unit is further configured to determine a further oscillation behavior of the further circuit section by sampling the plurality of defined frequencies, and to determine a change to a parameter of the circuit section through a comparison of the oscillation behavior with the further oscillation behavior.

14. A sensor comprising:
a circuitry having at least one oscillating circuit section, wherein the circuit section comprises a circuit component configured to be affected by an external influence, such that an oscillation behavior of the circuit section can be altered by the external influence, wherein the circuitry is also configured to determine the oscillation behavior of the circuit section by sampling a plurality of defined frequencies; and
a moving, actuator that is at least partially electrically conductive, wherein the actuator is configured such that an actuation of the actuator causes the external influence.

15. A method for determining an oscillation behavior of an oscillating circuit section of a circuitry, comprising:
affecting a circuit component comprised by the circuit section through an external influence, such that the oscillation behavior of the circuit section is altered by the external influence; and
sampling the oscillation behavior of the circuit section at a plurality of defined frequencies, in order to determine the oscillation behavior.

16. The sensor according to claim 14, wherein the actuator is spaced apart from the circuit section and the actuation of the actuator occurs when the spacing from the actuator to the circuit section is altered.

17. The sensor according to claim 14, further comprising a frequency generator configured to provide the plurality of defined frequencies to the circuit section.

18. The sensor according to claim 14, further comprising an evaluation unit coupled to the circuit section, wherein the evaluation unit is configured to detect, via the coupling, at least one signal strength of the circuit section, in each case, at frequencies of the plurality of defined frequencies.

19. The sensor according to claim 18, wherein the evaluation unit is configured to determine an extreme of the oscillation behavior based on the detected signal strengths, wherein the plurality of defined frequencies comprise at least one first frequency, one second frequency and one third frequency, wherein a second signal strength at the second frequency is different than a first signal strength at the first frequency and a third signal strength at the third frequency, wherein the first frequency is lower than the second frequency, and the third frequency is higher than the second frequency, wherein the evaluation unit is configured to determine the extreme of the oscillation behavior through interpolation, based at least on the first signal strength, the second signal strength and the third signal strength.

20. The sensor according to claim 18, further comprising a further oscillating circuit section, wherein the evaluation unit is further configured to determine a further oscillation behavior of the further circuit section by sampling the plurality of defined frequencies, and to determine a change to a parameter of the circuit section through a comparison of the oscillation behavior with the further oscillation behavior.
